(19) United States
(12) Patent Application Publication
(10) Pub. No.: US 2014/0327586 A1
(43) Pub. Date: Nov. 6, 2014

(54) Reflective Ellipsoid Chamber

(71) Applicant: The Howland Company, Buford, GA (US)

(72) Inventor: James D. Huff, Sugar Hill, GA (US)

(73) Assignee: The Howland Company, Buford, GA (US)

(21) Appl. No.: 14/268,570

(22) Filed: May 2, 2014

Related U.S. Application Data
(60) Provisional application No. 61/819,283, filed on May 3, 2013.

(51) Int. Cl. G01R 29/10

(52) U.S. Cl. CPC G01R 29/105
USPC 343/703

(57) ABSTRACT

A test chamber for measuring total radiated power, total isotropic sensitivity, and antenna efficiency is disclosed. The chamber takes the shape of a hollow ellipsoid. RF energy radiated from one focal point of the ellipse reflects off the walls of the ellipse and is collected at the second focal point of the ellipse. A single power measurement at the second focal point measures the total power radiated from the first focal point. The subject matter of the present disclosure significantly reduces the measurement time for these three parameters, and is applicable to the design, production, and repair of antennas and wireless devices.

### CROSS REFERENCE TO RELATED APPLICATIONS

The present non-provisional patent application claims priority to, and the full benefit of, U.S. Provisional Patent Application No. 61/819,283, filed May 3, 2013, entitled “Reflective Ellipsoid Chamber,” the entire content of which is incorporated herein by reference.

### TECHNICAL FIELD

The present invention relates, generally, to test chamber apparatus for use in association with wireless network-enabled devices and antennas; and, more particularly, to reflective ellipsoid test chamber apparatus and associated processes for use in association with the testing of antennas and wireless network-enabled devices.

### BACKGROUND

Developers, manufacturers, network operators, and/or testing facilities of wireless equipment, such as by way of non-limiting example, cellular network-enabled devices and/or antennas, IEEE 802.11 wireless-enabled devices and/or antennas, and any other devices and/or antennas utilizing wireless radio frequency (RF) transmission and/or reception, must test to ascertain whether the devices meet their corresponding design and operational specifications. It is well-known in the industry that, with currently available technologies, such testing is time consuming, labor intensive, and requires sophisticated and expensive equipment. The associated equipment and testing facilities often take-up a considerable amount of physical space; to wit, they have a large physical footprint. It is often the case that several classes of measurements are required in order to certify a particular device, with multiple, discrete measurements being required for each measurement class.

For example, it is often necessary to measure the total power actually radiated by an antenna. In the current state of the art, this measurement is made by positioning a measurement antenna at different points on an imaginary spherical surface surrounding the antenna and measuring the power received at each point. The power measured at the individual points is then summed to determine the total radiated power (TRP). These measurements are typically made in an anechoic chamber—a chamber configured to absorb unwanted reflected radiation, so that echos are reduced or eliminated—using a two axis mechanical positioner to change the relative position of the measurement antenna and the device being tested. The accuracy of the TRP measurement depends upon the number of points sampled, and a typical test scenario requires 264 separate measurements.

The total isotropic sensitivity (TIS) of an antenna/receiver combination is measured in a similar fashion, except that, in this case, the measurement antenna transmits a signal to the device under test (DUT). At each point on the surface of the imaginary sphere surrounding the DUT, the transmitted power level is decreased until the receiver noise floor is reached. Again, the individual measurements are summed in order to determine the isotropic sensitivity of the antenna/receiver combination.

Typically, TRP measurement times range from two to five minutes per channel, and a single channel TIS measurement can take more than one hour. When multiple channels must be tested in multiple frequency bands with the DUT (e.g., a cellular telephone handset) set up for operation in any of a variety of configurations, test times for a single device can, disadvantageously, total more than forty hours. Clearly, when multiple devices must be tested, the process can be extraordinarily time consuming, labor intensive, and expensive.

Additionally, in accordance with the current state of the art, a complete test system typically consists of an electromagnetically shielded room, lined with one or more materials acting to absorb microwaves. This shielded, lined room houses a dual-axis, mechanical positioning system for the DUT. Very often, the cost of the test chamber, plus necessary test instruments, can approach one million dollars (USD).

In view of the above discussion, it would be advantageous to reduce testing times, labor and equipment costs, and physical space requirements, while increasing test accuracy, DUT throughput rates, and the like. Accordingly, it is to the disclosure of such devices and related systems that this disclosure is directed.

### SUMMARY

In order to provide the advantages identified above, the subject matter of the present disclosure provides a hollow chamber in the shape of an ellipsoid to collect, at a first focal point, the energy transmitted from a device located at a second focal point of the ellipsoid. The inside walls of the ellipsoid chamber are conductive in order to reflect the electromagnetic waves radiated by the transmitting device. Energy collected at the first focal point is received by an antenna and passed to appropriate measurement instruments, typically via a coaxial cable. A unique attribute of the present subject matter is the ability to collect essentially all of the energy radiated by a device, in essentially every direction, at essentially a single point.

These and other features and advantages of the various embodiments of devices and related systems, as set forth within the present disclosure, will become more apparent to those of ordinary skill in the art after reading the following Detailed Description of Illustrative Embodiments and the Claims in light of the accompanying drawing Figures.

### BRIEF DESCRIPTION OF THE DRAWINGS

Accordingly, the within disclosure will be best understood through consideration of, and with reference to, the following drawing Figures, viewed in conjunction with the Detailed Description of Illustrative Embodiments referring thereto, in which like reference numbers throughout the various Figures designate like structure, and in which:

FIG. 1 is a cross-section of a representative embodiment of a reflective ellipsoid test chamber apparatus according to the present disclosure, illustrating how power is transferred between the two focal points of an ellipsoid;

FIG. 2 illustrates how an ellipsoid test chamber apparatus according to FIG. 1 can be configured to measure the efficiency of an antenna;

FIG. 3 illustrates how an ellipsoid test chamber apparatus according to FIG. 1 can be configured to measure the total radiated power of a cell phone;

FIG. 4 illustrates how an ellipsoid test chamber apparatus according to FIG. 1 can be configured to measure the total isotropic sensitivity of a cell phone;

FIG. 5 illustrates an alternative ellipsoid test chamber apparatus configuration for measuring total isotropic sensitivity; and

FIG. 6 provides a representative flow chart of a total radiated power measurement of a wireless cellular device, taking the form of a cellular phone handset, using an ellipsoid test chamber apparatus according to the present disclosure.

It is to be noted that the drawings presented are intended solely for the purpose of illustration and that they are, therefore, neither desired nor intended to limit the invention to any or all of the exact details of construction shown, except insofar as they may be deemed essential to the claimed invention.

### REPRESENTATIVE REFERENCE DESIGNATIONS USED IN THE FIGURES

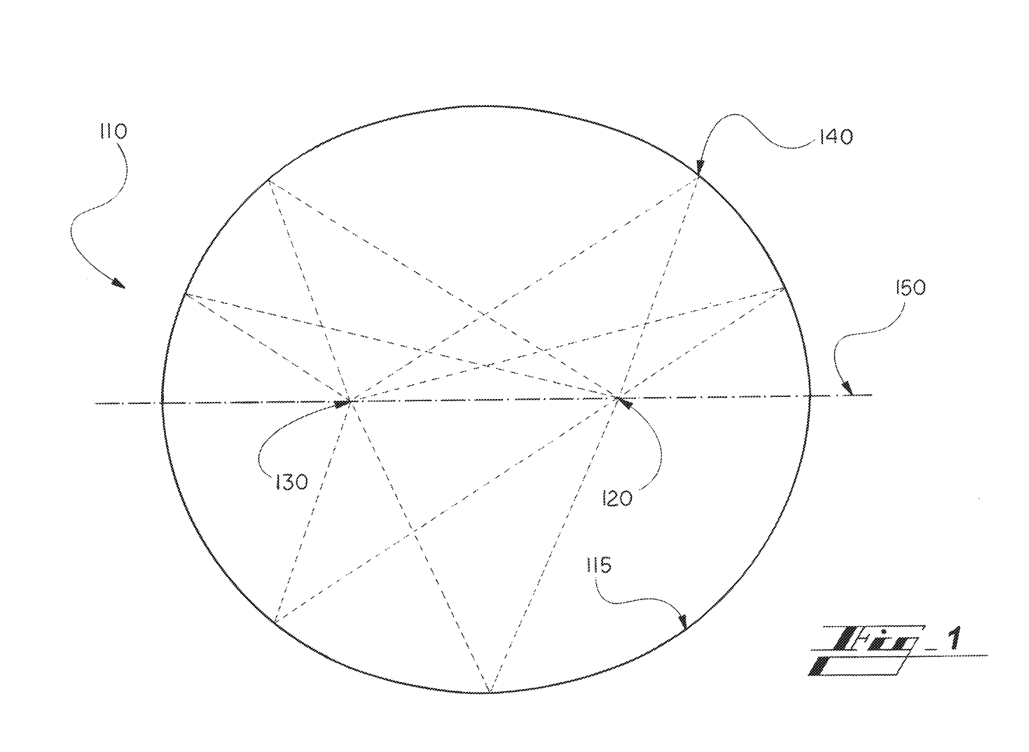

In FIGS. 1-5, the following representative reference designations are used:

110 An ellipsoid; ellipsoid chamber

115 A conductive surface of an ellipsoid

120 A first of two focal points

130 A second of two focal points

140 An arbitrary point on the surface of the ellipsoid

150 An axis of rotation of the ellipsoid

160 A physical support structure of the ellipsoid surface

170 A measurement antenna

180 A communication antenna

190 A device under test (DUT)

200 A cellular base station simulator

210 A power measurement device

220 A signal generator

230 A coaxial cable

240 A coaxial cable

### DETAILED DESCRIPTION OF ILLUSTRATIVE EMBODIMENTS

In describing the several embodiments illustrated in the Figures, specific terminology is employed for the sake of clarity. The invention, however, is not intended to be limited to the specific terminology so selected, and it is to be understood that each specific element includes all technical equivalents that operate in a similar manner to accomplish a similar purpose. Additionally, in the Figures, like reference numerals shall be used to designate corresponding parts throughout the several Figures.

It will be understood and appreciated by those of ordinary skill in the art that the subject matter of the present disclosure is intended for operation and use in association with any of a variety of broad classes of wireless RF equipment, such as by way of non-limiting example, cellular network-enabled devices and/or antennas, IEEE 802.11 wireless-enabled devices and/or antennas, and any other devices and/or antennas utilizing wireless radio frequency (RF) transmission and/or reception, without limitation. Accordingly, any particular device(s) and/or antennas described and/or designated within the present disclosure are for illustrative purposes only, and are to be understood and treated only as non-limiting examples.

Illustrated in FIG. 1 is ellipsoid 110 that is obtained by rotating an ellipse about axis 150 that passes through two focal points 120, 130 of the ellipse. A characteristic of an ellipsoid is that the distance from first focal point 120 to a point 140 on the surface of ellipsoid 110 and back to second focal point 130 is the same for all points on surface of the ellipsoid. From a practical standpoint, this means that if a radio frequency signal is transmitted from a point source at first focal point 120, it will reflect off of a conductive surface 115 of ellipsoid 110 and arrive at second focal point 130 in-phase with reflected signals from all the points on the surface of ellipsoid 110. Hence, ellipsoid 110—in physical form comprising hollow, ellipsoid chamber 110—can collect essentially all of the RF energy from a transmitting antenna at first focal point 120 and focus it back to a receiving antenna located at second focal point 130.

The physical dimensions of an ellipsoid chamber 110 formed according to the above-described characteristics will depend upon several factors, primarily including the frequency of operation, the maximum measurement uncertainty allowed, and the size of the devices to be tested. Any of a variety of configurations are possible based upon the relative importance of these parameters.

For example, in some embodiments, a configuration of ellipsoid chamber 110 might be established premised upon the following several parameters. First, the transmitting and receiving antennas should be far enough apart that the receiving antenna is within the radiating field of the transmitting antenna. This is generally accepted to be a distance of three wavelengths. Accordingly, this parameter then sets the minimum distance between foci 120, 130. Second, if the walls of ellipsoid chamber 110 are too close to the transmitting (or receiving) antenna, the characteristics of the antenna can be negatively impacted or undesirably changed. A minimum separation of two wavelengths from foci 120, 130 to the walls of ellipsoid chamber 110 is generally considered to be sufficient. Accordingly, this parameter then establishes the major axis of the ellipse, or the elliptical cross-section, at 7 wavelengths and the minor axis at 6.3 wavelengths.

If one uses these parameters to design an ellipsoid chamber 110 to operate from 700 MHz to 6 GHz, the inside dimensions of ellipsoid chamber 110 will be 3.0 meters long and 2.7 meters high at its center. Increasing the frequency range of the ellipsoid chamber to cover 400 MHz to 6 GHz would require increasing the size of the ellipsoid to 17.2 feet long by 15.5 feet high. Of course, smaller chambers are also possible for measuring small devices operating at higher frequencies. Of course, the above illustrated design parameters and frequency ranges are representative only, and are not meant in any way to limit the scope of subject matter of the present disclosure.

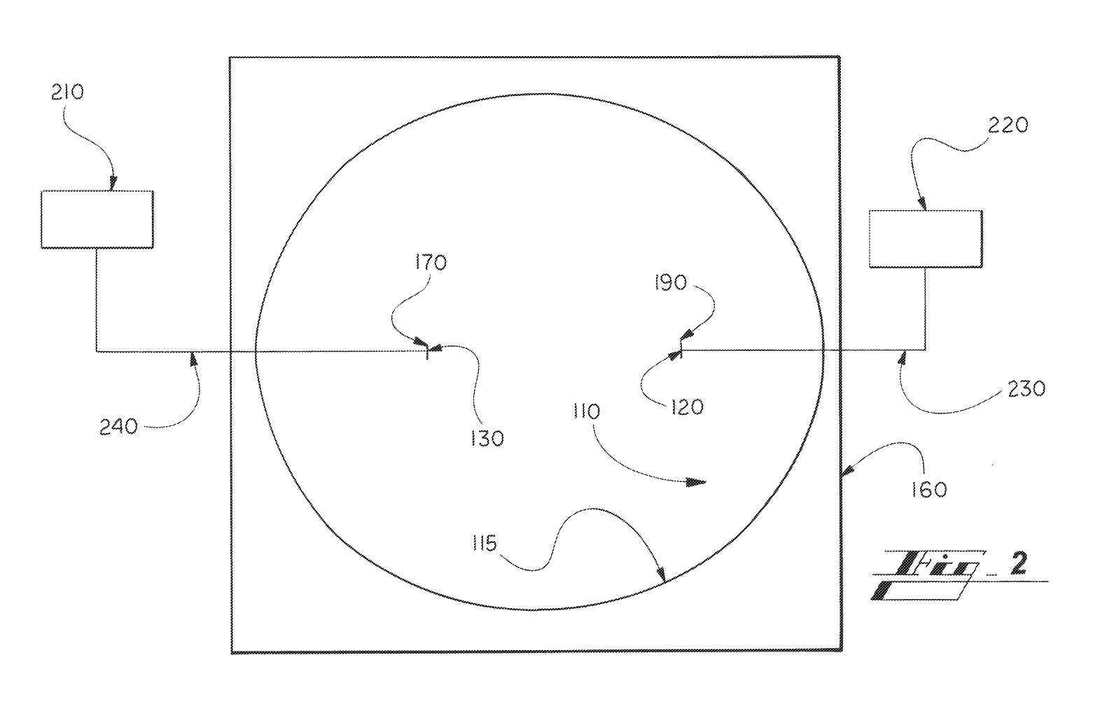

With general reference to FIGS. 2-5, measurement antenna 170 is located at second focal point 130 of ellipsoid chamber 110. Antenna 170 will receive RF signals if a power measurement is being made, and will transmit RF signals if a receiver sensitivity measurement is being made. Ellipsoid chamber 110 is reciprocal; that is, its characteristics are the same, without regard to whether the measurement antenna is transmitting or receiving. The discussion that follows assumes that the measurement antenna is receiving, but it is equally appropriate and valid if the measurement antenna is transmitting.

Measurement antenna 170 shown in FIGS. 2-4 is a simple, folded dipole. It is linearly polarized and typically has a 10% bandwidth. In order to capture essentially all of the power present at the focal point, it will be necessary to make two measurements, with the dipole rotated 90 degrees between measurements. In other embodiments, a dual-polarized antenna could also be used to remove the requirement of rotating the measurement antenna. In such embodiments, a cross-dipole would be an example of one such antenna. Alternately, measurement antenna 170 may remain fixed and the device under test or the antenna under test may be rotated 90 degrees in order to capture the energy present in two orthogonal polarizations.

In order to increase the bandwidth of measurement antenna 170, one could use the dipole over a wider bandwidth and add a correction factor for its mismatch. Alternatively, and in some embodiments, one could use a wide-bandwidth horn, such as a quad-ridged horn, and, again, include the necessary correction factors. Many choices are available for the measurement antenna, and the appropriate selection for a particular application will most often require one to decide amongst necessary tradeoffs between test times and measurement uncertainty.

Inside surface 115 of ellipsoid chamber 110 must be conductive in order to efficiently reflect the RF energy transmitted from one focal point back to the other focal point. In some embodiments, silver and/or copper walls would be efficient reflectors. Notwithstanding, any power losses due to, or associated with, finite resistance of the surface of ellipsoid chamber 110 can be calibrated out. In fact, in some applications, it may be desirable to intentionally design ellipsoid chamber 110 with resistive walls in order to attenuate multiple reflections within the chamber.

It is noted that, in some embodiments, a lossy dielectric window can also be used to attenuate multiple reflections within the chamber. In some embodiments, the lossy dielectric window is positioned between the measurement antenna and the device under test. In such embodiments, the lossy window is selected to provide approximately 20 dB of loss between the two antennas.

Inside surface 115 of ellipsoid chamber 110 must be an accurate representation of the theoretical ellipsoid in order to collect the energy from one focal point at the other; however, it can never be perfect. Accordingly, deviations from a perfect ellipsoid will increase the uncertainty of a particular measurement. Because it is contemplated that larger ellipsoid chambers 110 will be made in sections in order to facilitate installation in existing buildings, care must be taken in the manufacturing and assembly of the sections to maintain the surface accuracy of the ellipsoid.

With this in mind, and returning to FIGS. 2-4, it is important that support structure 160 for inside surface 115 of ellipsoid chamber 110 maintain the accuracy of the shape of the ellipsoid over changes in the environment. Many different configurations and materials can be used in support structure 160, so long as it is stable over time in the environment in which ellipsoid chamber 110 is installed and operated. Choices for support structure 160 include aluminum or steel weldments, molded honeycomb materials, fiberglass, and, in some applications and embodiments, possibly high density polystyrene.

Ellipsoid chamber 110 can be configured to measure the efficiency of an antenna, as shown in FIG. 2. Device under test 190 is placed at first focal point 120 and connected to signal generator 220, in some embodiments, preferably via coaxial cable 230. Measurement antenna 170 is placed at second focal point 130 and connected to a power measurement device 210, in some embodiments preferably via coaxial cable 240. The efficiency of device under test 190 is the difference between the input power to device under test 190 and the power received by power measurement device 210, corrected by the appropriate calibration factor, to be discussed in greater detail hereinbelow.

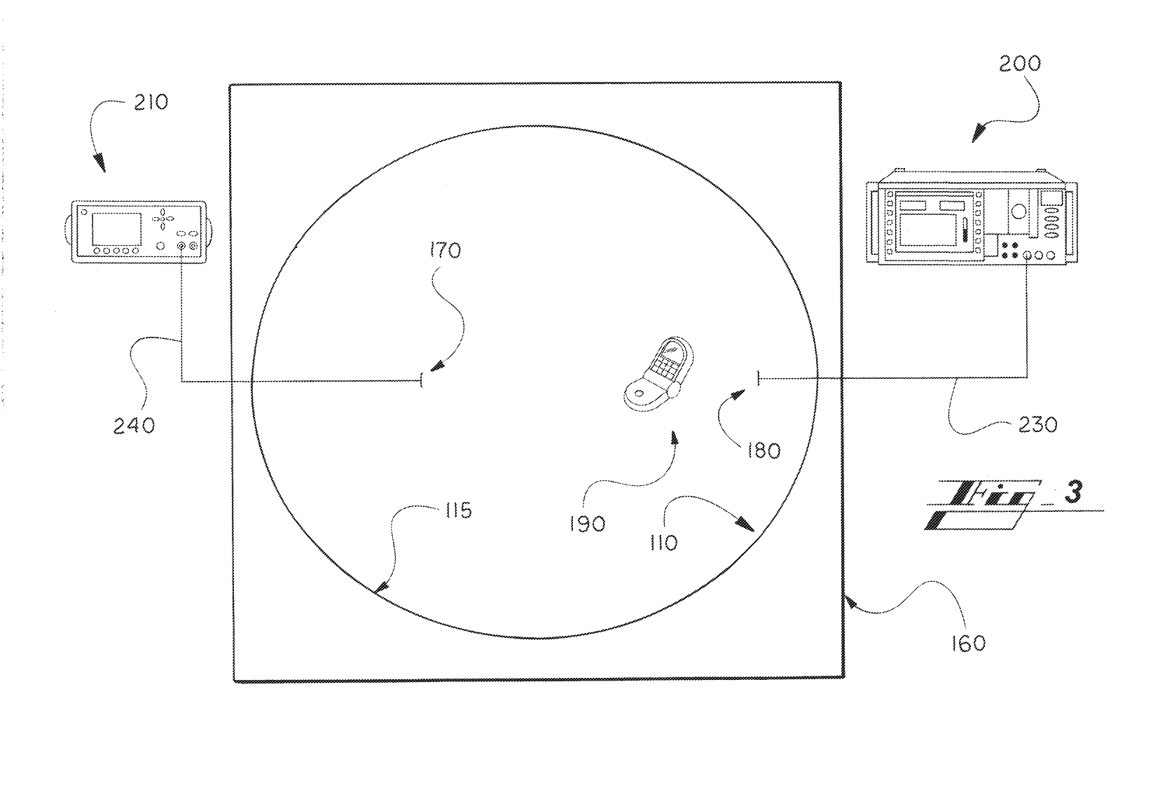

Ellipsoid chamber 110 can be configured for measurement of total radiated power from a device under test 190, as shown in FIG. 3. Device under test 190, in this example, is a wireless cellular handset. Device under test 190 is placed at first focal point 120. Measurement antenna 170 is placed at second focal point 130 and connected, in some embodiments, preferably via coaxial cable 240 to power measurement receiver 210. Power measurement receiver 210 is located external to ellipsoid chamber 110. In order for device under test 190 to transmit, it must be connected to base station simulator 200. This connection is provided via communication antenna 180 internal to ellipsoid chamber 110 and connected, in some embodiments, preferably via a coaxial cable 230 to base station simulator 200.

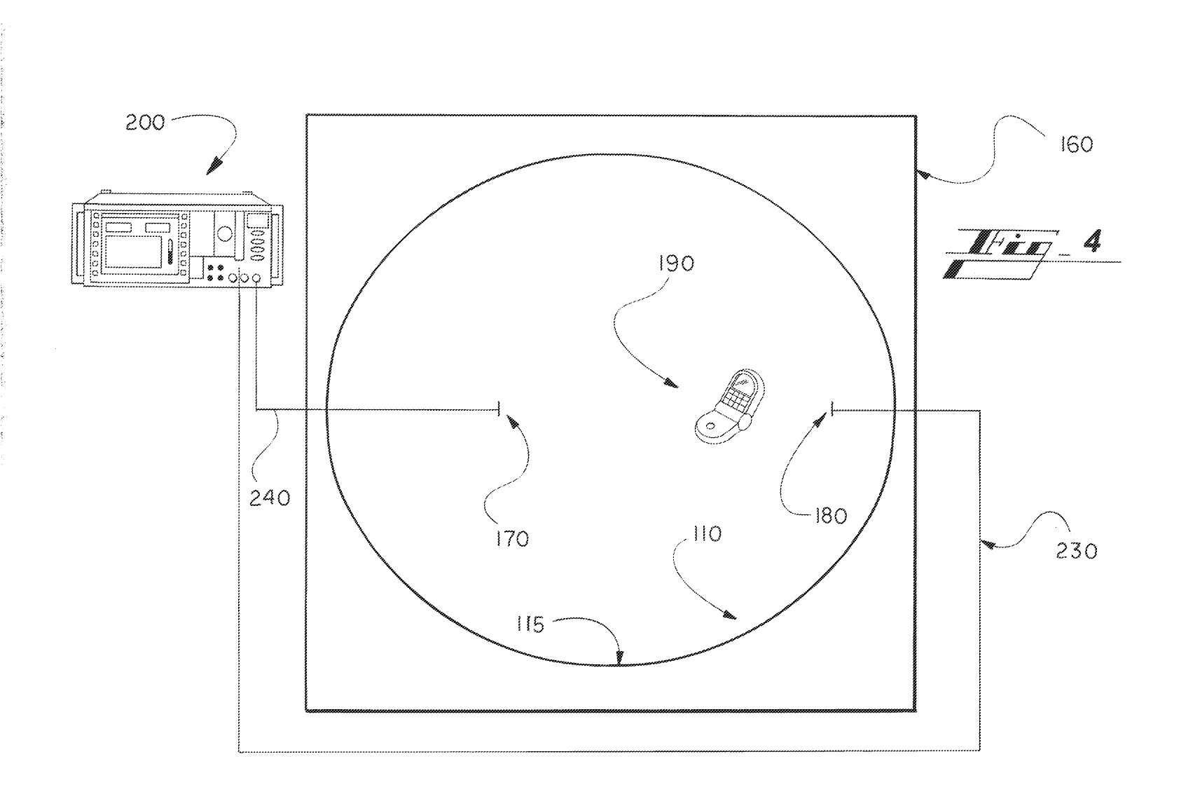

Ellipsoid chamber 110 can be configured for the measurement of total isotropic sensitivity of device under test 190, as shown in FIG. 4. Device under test 190, in this example, is, again, a wireless cellular handset. Device under test 190 is placed at first focal point 120. Measurement antenna 170 is placed at second focal point 130 and connected, in some embodiments, preferably via a coaxial cable 240 to cellular base station simulator 200. Communication antenna 180 is also connected to cellular base station simulator 200, in some embodiments, preferably via a coaxial cable 230.

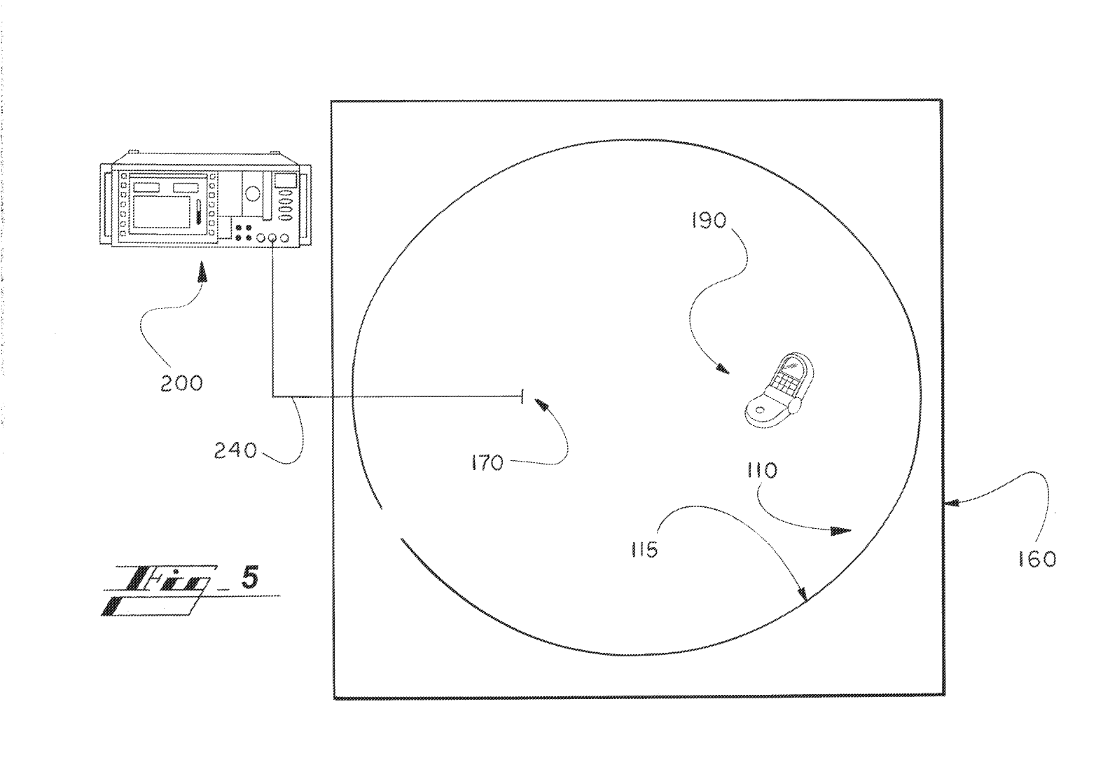

Turning now to FIG. 5, an alternative embodiment of ellipsoid chamber 110 is shown, configured for measuring total isotropic sensitivity of device under test 190. Device under test 190, in this example, is, again, a wireless cellular handset. Device under test 190 is placed at first focal point 120. Measurement antenna 170 is placed at second focal point 130 and connected, in some embodiments, preferably via a coaxial cable 240 to cellular base station simulator 200. In this embodiment, measurement antenna 170 may also and dually function as a communication antenna, replacing communication antenna 180 of FIG. 4.

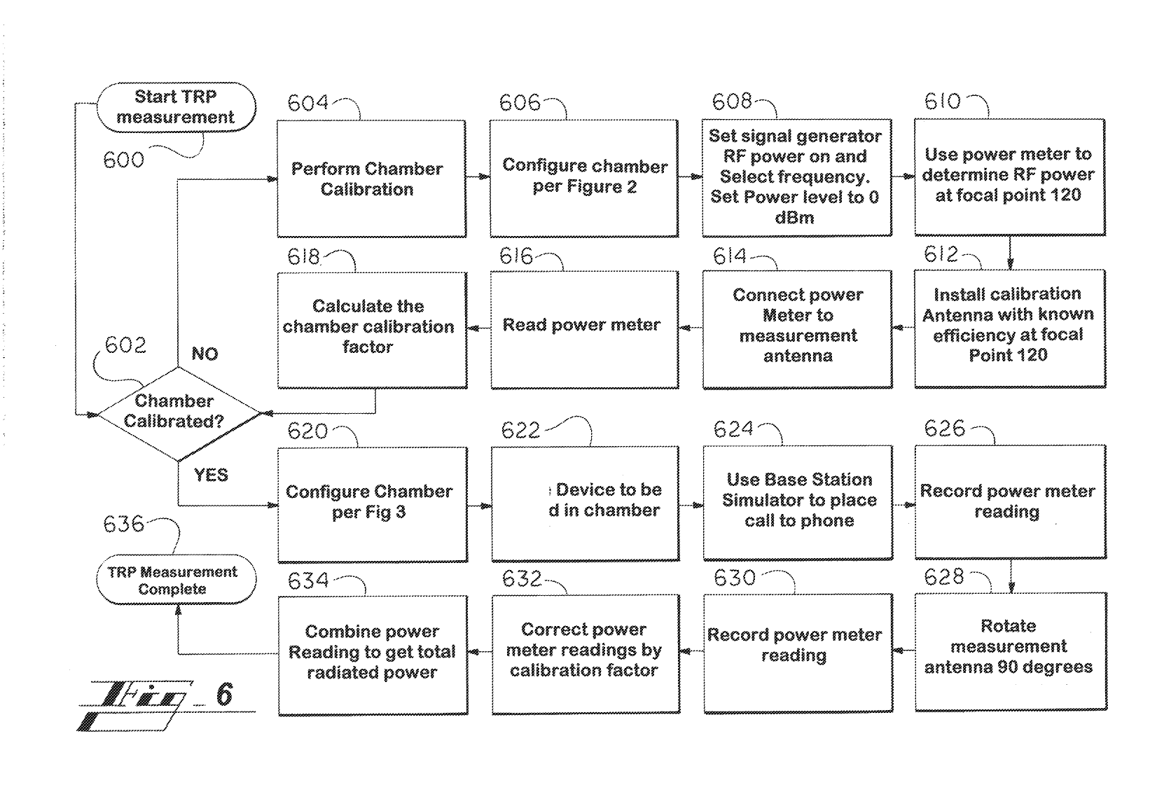

Turning now, generally, to FIG. 6, in order to make accurate measurements in ellipsoid chamber 110, it will be necessary to determine one or more appropriate calibration factor for ellipsoid chamber 110. This calibration factor is a sum of the power losses in ellipsoid chamber 110 and will vary with frequency. For example, there will be power losses due to the finite conductivity of the chamber walls, losses due to the efficiency of the measurement antenna, and losses in the coaxial cable that connects the measurement antenna to the power measurement receiver. The value of the individual components is not needed. One simply needs to measure the total loss in order to determine the chamber calibration factor.

The procedure is fairly simple. Generally, one configures ellipsoid chamber 110 per FIG. 2. A calibration standard antenna of known efficiency is installed as device under test 190. Both the RF power level into the calibration standard antenna and the power out of measurement antenna 170 are recorded. The calibration factor for ellipsoid chamber 110 is the power into the calibration antenna, minus the efficiency losses in the calibration antenna, minus the power received by measurement antenna 170.

FIG. 6 depicts a detailed flowchart of the general procedures described above. One starts TRP measurement at step 600. At step 602, a determination is made as to whether ellipsoid chamber 110 is already calibrated, or needs to be calibrated. If ellipsoid chamber 110 requires calibration, chamber calibration proceeds at step 604. At step 606, ellipsoid chamber 110 is configured as described with reference to FIG. 2. At step 608, signal generator 220 RF power is turned on and appropriate frequency selection is made. Power level is set to 0 dBm. At step 610, a power meter is used to determine the RF power at first focal point 120. At step 612, a calibration antenna with known efficiency is installed at first focal point 120. At step 614, the power meter is connected to measurement antenna 170. At step 616, a reading is taken from the power meter. At step 618, the calibration factor is calculated for ellipsoid chamber 110.

With continuing reference to FIG. 6, once the chamber is calibrated and the calibration factor has been ascertained, TRP measurement may continue from calibration determination step 602. At step 620, ellipsoid chamber 110 is configured as described with reference to FIG. 3. At step 622, a device under test 190 is placed into ellipsoid chamber 110. As before, in this example, device under test 190 continues to be a wireless cellular handset. At step 624, base station simulator 200 is used to place a call to device under test 190. At step 626, a power meter reading is recorded. At step 628, and in the embodiment of this configuration, measurement antenna 170 is rotated 90 degrees. At step 630, a power meter reading is again recorded. At step 632, the power meter readings taken at steps 626, 630 are corrected by the calibration factor that was determined above at step 618. At step 634, the corrected power readings are combined to yield the total radiated power. If successful, TRP measurement for device under test 190 are concluded at step 636.

If any step fails, it will be appreciated that the entire process set forth in FIG. 6 may be repeated. In appropriate circumstances, the process described in FIG. 6 may be restarted at the failed step, or it may be restarted at any appropriate prior step authorized by the testing specification being utilized.

By now it will be seen that use of ellipsoid chamber 110 according to the present disclosure offers several significant benefits and advantages over the known prior art when used to test wireless devices. The first, of course, is the reduction in test time. A reduction in test time reduces the capital investment and labor costs for a manufacturer, because fewer chambers are required for the same number of devices being tested. A reduction in test time also allows a manufacturer to bring new products to market sooner. A second benefit accruing from use of ellipsoid chamber 110 according to the present disclosure is that it is much simpler to use and operate than the prior art anechoic chamber currently used to test wireless devices. As a result, testing is less costly and more reliable. Of course, each of the above benefits and advantages translate into lower research and development costs for developers of wireless devices.

The previous discussions have focused on use of ellipsoid chamber 110 to test antennas and wireless devices; however, there are, perhaps, broader applications for such an ellipsoid chamber as has been described herein. The fundamental characteristic of the ellipsoid chamber is that it takes energy generated at one point in space and collects it at another point in space. In a sense, one is moving the energy from point A to point B with very high efficiency. Accordingly, ellipsoid chamber 110, or an appropriate embodiment thereof, could be used in medical applications where it is advantageous to focus RF energy at a point in, or on, a patient's body. It could also be used to deliver high power RF energy to an internal component or region of a device, for example, in order to cure an adhesive. It could be used in testing the RF immunity of a device by providing a highly concentrated RF signal on the device being tested. It is believed that ellipsoid chamber 110, or an appropriate embodiment thereof, can be used in these and many other applications.

Accordingly, and having thus described exemplary embodiments of the subject matter of the present disclosure, it is noted that the within disclosures are exemplary only and that various other alternatives, adaptations, and modifications may be made within the scope and spirit of the present invention. For each of these reasons, and others, the present subject matter is not limited to the specific embodiments as illustrated herein, but is only limited by the following claims.

What is claimed:

1. A chamber for testing a wireless device or antenna, the chamber comprising a substantially ellipsoid-shaped internal wall.

2. The chamber of claim 1 further comprising an axis of rotation of said ellipsoid.

3. The chamber of claim 1 further comprising a first focal point and a second focal point.

4. The chamber of claim 1 wherein said chamber is configured to collect a substantial portion of the energy radiated by a wireless device, in substantially every direction, at substantially a single point.

5. The chamber of claim 1 wherein said internal wall is highly conductive.

6. The chamber of claim 1 wherein said internal wall has at least some measurable resistance.

7. The chamber of claim 1 further comprising a first antenna and a second antenna, and wherein said first and second antennas are separated by a distance of at least approximately three wavelengths.

8. The chamber of claim 1 further comprising a comprising a first focal point at which a first antenna is located and a second focal point at which a second antenna is located, said wall of said ellipsoid chamber comprising a minimum separation of at least approximately two wavelengths from each said focal point.

9. The chamber of claim 1 further comprising a major axis of approximately 7 wavelengths and a minor axis of approximately 6.3 wavelengths.

10. The chamber of claim 1 further comprising a measurement antenna.

11. The chamber of claim 10 wherein said measurement antenna comprises a simple, folded dipole.

12. The chamber of claim 10 wherein said measurement antenna comprises a dual-polarized antenna.

13. The chamber of claim 12 wherein said dual-polarized antenna comprises a cross-dipole.

14. The chamber of claim 1 further comprising a lossy dielectric window for attentuating multiple reflections within said chamber.

15. A method for measuring total radiated power within an ellipsoid chamber, the method comprising the steps of:
a. placing a device under test at a first focal point of said ellipsoid chamber;
b. placing a measurement antenna at a second focal point of said ellipsoid chamber;
c. connecting said measurement antenna to a power measurement receiver located external to said ellipsoid chamber;
d. connecting the device under test to a base station simulator via a communication antenna internal to said ellipsoid chamber; and
e. capturing the energy present in two orthogonal polarizations.

16. The method of claim 15 wherein said measurement antenna is connected to said power measurement receiver via coaxial cable.

17. The method of claim 15 wherein said communication antenna internal to said ellipsoid chamber is connected to said base station simulator via coaxial cable.

18. A method for measuring total isotropic sensitivity within an ellipsoid chamber, the method comprising the steps of:
a. placing a device under test at a first focal point of said ellipsoid chamber;
b. placing a measurement antenna at a second focal point of said ellipsoid chamber;
c. connecting said measurement antenna to a cellular base station simulator;
d. connecting a communication antenna to said cellular base station simulator and;
e. capturing the energy present in two orthogonal polarizations.

19. The method of claim 18 wherein said measurement antenna is connected to said cellular base station simulator via coaxial cable.

20. The method of claim 18 wherein said communication antenna internal to said ellipsoid chamber is connected to said cellular base station simulator via coaxial cable.
